(19) United States
(12) Patent Application Publication
(10) Pub. No.: US 2022/0373786 A1
(43) Pub. Date: Nov. 24, 2022

(54) OPTICAL REFLECTOR ELEMENT AND OPTICAL REFLECTOR SYSTEM

(71) Applicant: Panasonic Intellectual Property Management Co., Ltd., Osaka (JP)

(72) Inventors: Kensuke MIHARA, Osaka (JP); Kazuki KOMAKI, Osaka (JP); Ryouichi TAKAYAMA, Osaka (JP)

(21) Appl. No.: 17/882,304

(22) Filed: Aug. 5, 2022

Related U.S. Application Data
(63) Continuation of application No. PCT/JP2021/012089, filed on Mar. 23, 2021.

(30) Foreign Application Priority Data
Mar. 25, 2020 (JP) 2020-054742

(51) Int. Cl. G02B 26/08

(52) U.S. Cl. CPC G02B 26/0858

(57) ABSTRACT

An optical reflector element includes: a pair of vibrator groups each of which includes tuning fork vibrators that are coupled together such that vibration centers of the tuning fork vibrators align on an imaginary rotational axis; a reflective body interposed between the pair of vibrator groups; a pair of supports that couple the pair of vibrator groups and the reflective body together; and a base to which the pair of vibrator groups are coupled in a manner that allows the pair of vibrator groups to vibrate.

### CROSS REFERENCE TO RELATED APPLICATIONS

This is a continuation application of PCT International Application No. PCT/JP2021/012089 filed on Mar. 23, 2021, designating the United States of America, which is based on and claims priority of Japanese Patent Application No. 2020-054742 filed on Mar. 25, 2020. The entire disclosures of the above-identified applications, including the specifications, drawings and claims are incorporated herein by reference in their entirety.

### FIELD

The present disclosure relates to an optical reflector element and an optical reflector system which cause a position irradiated with laser light and the like to reciprocate using reflection.

### BACKGROUND

Optical reflector element that includes two tuning fork vibrators connected to two sides of a reflective body, and causes the reflective body to rotationally vibrate by causing the two tuning fork vibrators to vibrate is available (for example, see Patent Literature (PTL) 1).

### CITATION LIST

### Patent Literature

PTL 1: Japanese Patent No. 5045470

### SUMMARY

### Technical Problem

When such an optical reflector element as described above is used as, for example, an element for image display, an increase in the rotational vibration frequency of a reflective body is desired. However, the inventors have found that, in conventional optical reflector elements, an increase in the driving frequency of a driving means that vibrates a tuning fork vibrator increases torque required for a reflective body to produce rotational vibrations, and shortens the life until the optical reflector element is damaged. The inventors have also found the need to decrease an oscillation angle of the reflective body for ensuring long life while maintaining high frequency.

In view of the above, the present disclosure aims to provide an optical reflector element and an optical reflector system which can ensure long life, while reducing a decrease in an oscillation angle even if the rotational vibration frequency of a reflective body is increased.

### Solution to Problem

An optical reflector element according to one aspect of the present disclosure includes: vibrator groups each of which includes tuning fork vibrators that are coupled together such that vibration centers of the tuning fork vibrators align on an imaginary rotational axis; a reflective body; supports that couple the vibrator groups and the reflective body together; and a base to which the vibrator groups are coupled in a manner that allows the vibrator groups to vibrate.

The optical reflector element according to one aspect of the present disclosure includes: a pair of vibrator groups each of which includes tuning fork vibrators that are coupled together such that vibration centers of the tuning fork vibrators align on an imaginary rotational axis; a reflective body interposed between the pair of the vibrator groups; a pair of supports that couple the pair of the vibrator groups and the reflective body together; and a base to which the pair of the vibrator groups are coupled in a manner that allows the pair of the vibrator groups to vibrate.

An optical reflector system according to one aspect of the present disclosure includes: vibrator groups each of which includes tuning fork vibrators that are coupled together such that vibration centers of the tuning fork vibrators align on an imaginary rotational axis; a reflective body interposed between the vibrator groups; supports that couple the vibrator groups and the reflective body together; a base to which the vibrator groups are coupled in a manner that allows the vibrator groups to vibrate; and driving means that drive the tuning fork vibrators such that rotational vibrations produced by the tuning fork vibrators in the vibrator groups are in phase around the rotational axis.

The optical reflector system according to one aspect of the present disclosure includes: a pair of vibrator groups each of which includes tuning fork vibrators that are coupled together such that vibration centers of the tuning fork vibrators align on an imaginary rotational axis; a reflective body interposed between the pair of the vibrator groups; a pair of supports that couple the pair of the vibrator groups and the reflective body together; a base to which the pair of the vibrator groups are coupled in a manner that allows the pair of the vibrator groups to vibrate; and driving means that drive the tuning fork vibrators such that rotational vibrations produced by the tuning fork vibrators in the vibrator groups are in phase around the rotational axis.

### Advantageous Effects

The present disclosure can realize a high vibration frequency, favorable oscillation angle characteristics, and long life.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a perspective view of an optical reflector element and an optical reflector system according to an embodiment.

FIG. 2 is a perspective view of an optical reflector element according to a variation.

### DESCRIPTION OF EMBODIMENT

Next, an embodiment of an optical reflector element and an optical reflector system according to the present disclosure will be described with reference to the drawings. Note that the embodiments below each describe a general or specific example. The numerical values, shapes, materials, structural elements, the arrangement and connection of the structural elements, steps, and orders of the steps, etc. presented in the embodiments below are mere examples, and are not intended to limit the present disclosure. Furthermore, among the structural elements in the embodiments below, those not recited in any one of the independent claims representing the most generic concepts will be described as optional structural elements.

In addition, the drawings are schematically illustrated. The structural elements in these schematic diagrams are emphasized, omitted, and/or proportionally adjusted as appropriate to describe the present disclosure. For this reason, the structural elements may have shapes, positional relationships, and/or proportions which are different from the actual shapes, positional relations, and/or proportions.

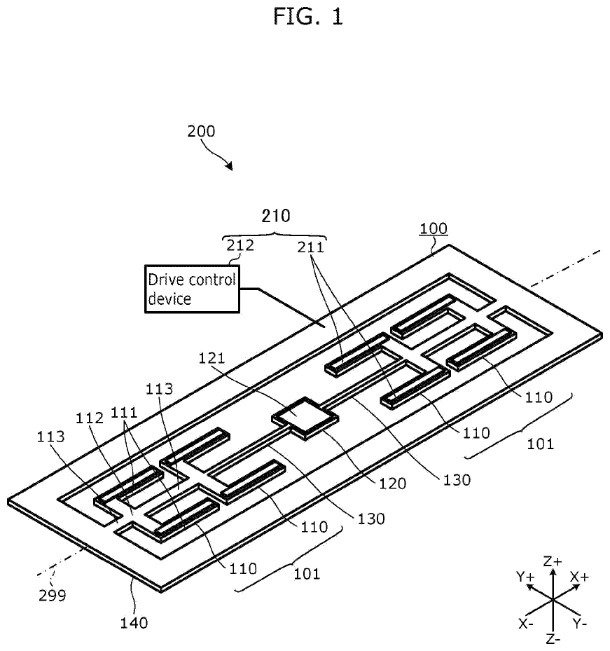

FIG. 1 is a perspective view of an optical reflector system according to the embodiment. Optical reflector system 200 includes optical reflector element 100 and a plurality of driving means 210. Optical reflector system 200 periodically changes an angle of reflecting light such as laser light, and periodically sweeps a position irradiated with laser light.

Optical reflector element 100 includes tuning fork vibrators 110, reflective body 120, supports 130, and base 140. In this embodiment, optical reflector element 100 is formed by removing unnecessary portions from a silicone substrate using an etching technique employed in semiconductor manufacturing processes. With this, a plurality of tuning fork vibrators 110, reflective body 120, a plurality of supports 130, and base 140 are integrally formed. Optical reflector element 100 is the so-called micro electro mechanical systems (MEMS). Note that driving members 211 included in driving means 210 and monitor elements (not illustrated) that detect the driving state of tuning fork vibrators 110 are formed on a surface of optical reflector element 100 using the MEMS technique in this embodiment.

Although a material that optical reflector element 100 includes is not particularly limited, a material having mechanical strength and a high Young's modulus, such as metal, crystal, glass, and resin, may be suitable. Specifically, a metal or an alloy, such as silicone, titanium, stainless steel, elinvar, and a brass alloy, exemplifies the material. The use of such metals, alloys, etc. can realize optical reflector element 100 that excels in vibration characteristics and processability.

Tuning fork vibrators 110 each are a member that produces vibrations having natural frequency (frequency) using driving means 210. Each tuning fork vibrator 110 includes pair of arms 111, connector 112 that connects end portions of pair of arms 111, and coupler 113 that couples tuning fork vibrator 110 and another part together.

In this embodiment, pairs of arms 111 are disposed in parallel with and along rotational axis 299 in a plane including rotational axis 299. Pairs of arms 111 are disposed substantially symmetrical about rotational axis 299. Connectors 112 are disposed so as to be orthogonal to respective pairs of arms 111 in the plane in which pairs of arms 111 are disposed. Couplers 113 extend along rotational axis 299 such that rotational axis 299 passes through their insides in the plane in which pairs of arms 111 are disposed. Couplers 113 are disposed such that couplers 113 protrude in a direction opposite a direction toward which pairs of arms 111 protrude with respect to connectors 112.

The plurality of tuning fork vibrators 110 are disposed on two sides of reflective body 120 in the rotational axis 299 direction. A plurality of tuning fork vibrators 110 on one side of reflective body 120 will be stated as vibrator group 101. Tuning fork vibrators 110 in each of vibrator groups 101 are disposed on the same plane, and aligned in a straight line and coupled together such that the entire vibration center of each tuning fork vibrator 110 is disposed on rotational axis 299. Each vibrator group 101 includes at least tuning fork vibrator 110 coupled to base 140 and tuning fork vibrator coupled to tuning fork vibrator 110 coupled to base 140.

A pair of vibrator groups 101 are disposed with reflective body 120 interposed therebetween such that the pair of vibrator groups 101 are equidistant from reflective body 120 within a single plane. Each of tuning fork vibrators 110 included in vibrator groups 101 is disposed such that a side to which connector 112 is not connected (hereinafter, stated as an “open-end side”) faces toward reflective body 120.

Around rotational axis 299, the pair of vibrator groups 101 have a shape such that a resonance frequency of the pair of vibrator groups 101 is substantially the same as a resonance frequency of rotational vibrations produced by reflective body 120. In this embodiment, all of tuning fork vibrators 110 excluding couplers 113 have substantially the same shape, and have a shape such that all of tuning fork vibrators 110 have substantially the same resonance frequency.

The torsional rigidity of coupling portions between base 140 and vibrator groups 101, namely, the torsional rigidity of couplers 113 of tuning fork vibrators 110 that are directly coupled to base 140, is set greater than the torsional rigidity of coupler 113 that couples tuning fork vibrators 110 in each vibrator group 101 together. In this embodiment, couplers 113 of tuning fork vibrators 110 closer to reflective body 120 and couplers 113 of tuning fork vibrators 110 farther away from reflective body 120 have substantially the same cross-sectional area size and the same cross-sectional shape orthogonal to rotational axis 299. For this reason, the length of couplers 113 farther away from reflective body 120 is shortened such that the torsional rigidity of couplers 113 farther away from reflective body 120 is greater than the torsional rigidity of couplers 113 closer to reflective body 120.

Reflective body 120 is a part disposed between the pair of vibrator groups 101. Reflective body 120 rotationally vibrates (rotationally oscillates) about rotational axis 299 and reflects light. Although the shape of reflective body 120 is not particularly limited, reflective body 120 in this embodiment is of a quadrilateral, plate-like shape, and includes, on its surface, reflector 121 that can reflect light to be reflected with high reflectance. A material that reflector 121 includes can be optionally selected. A metal or a metallic compound, such as gold, silver, copper, and aluminum, exemplifies the material. Moreover, reflector 121 may consist of two or more layers. Furthermore, reflector 121 may be provided by smoothly polishing a surface of reflective body 120. Reflector 121 may have a curved surface instead of a plane surface.

Supports 130 are bar-like parts that are disposed on respective two sides of reflective body 120 along rotational axis 299, and couple reflective body 120 and the pair of vibrator groups 101 together. Supports 130 function as torsion bars. In this embodiment, supports 130 are disposed such that rotational axis 299 passes through their insides. Supports 130 are parts that transmit, to reflective body 120, torque produced in vibrator groups 101 for causing reflective body 120 to rotationally vibrate. Supports 130 are twisted around rotational axis 299 to cause reflective body 120 to rotationally vibrate while holding reflective body 120.

The shape of supports 130 is not particularly limited, but supports 130 are members for causing reflective body 120 to rotationally vibrate by themselves being twisted. In this embodiment, the torsional rigidity of supports 130 is set less than the torsional rigidity of the coupling portion between tuning fork vibrators 110 in each vibrator group 101, namely, the torsional rigidity of coupler 113 of tuning fork vibrator 110 closer to reflective body 120. The area size of a cross section of supports 130 which is orthogonal to rotational axis 299 is set smaller than the area size of a cross section of couplers 113 of tuning fork vibrators 110 closer to reflective body 120. In this embodiment, the thickness (length in the Z axis direction as shown in the diagram) of couplers 113 and the thickness of supports 130 are the same. For this reason, the width (length in the Y axis direction as shown in the diagram) of supports 130 is less than the width of couplers 113. In the direction orthogonal to rotational axis 299 of the plane in which tuning fork vibrators 110 are disposed, one end of each support 130 is integrally connected to a center position of reflective body 120 and the other end of each support 130 is connected to a center of connector 112 of an inner tuning fork vibrator 110 among a pair of tuning fork vibrators 110. The cross-sectional shape of each support 130 which is perpendicular to rotational axis 299 is of a quadrilateral shape, and the thickness of each support 130 is the same as the thickness of reflective body 120 and other parts. Supports 130 have the same cross-sectional shape throughout, from reflective body 120 to the pair of vibrator groups 101. As described above, supports 130 having a uniform shape and a uniform area size along rotational axis 299 can be uniformly twisted as a whole when optical reflector element 100 is driven, thereby reducing the concentration of stress.

Base 140 is a part coupled to each of the pair of vibrator groups 101 in a manner that allows the pair of vibrator groups 101 to vibrate. Base 140 is a part used for attaching optical reflector element 100 to an external structural member and the like. In this embodiment, base 140 is a quadrilateral, frame-like member provided with, in its inside, the pair of vibrator groups 101, reflective body 120, and supports 130. Base 140 is disposed on a surface on which tuning fork vibrators 110 are disposed.

Driving means 210 are devices that produce driving force to cause the pair of vibrator groups 101 to rotationally vibrate for causing reflective body 120 to rotationally vibrate about rotational axis 299. A method that driving means 210 employs for causing respective tuning fork vibrators 110 to vibrate is not particularly limited. The use of a device that causes a magnetic field, an electric field, etc. to act on arms 111 of tuning fork vibrator 110 to cause tuning fork vibrator 110 to vibrate exemplifies the method. In this embodiment, each driving means 210 includes driving members 211 provided on respective surfaces of arms 111 using the MEMS technique, and drive control devices 212 that periodically deform driving members 211.

Driving members 211 produce driving force for causing the open-end sides of arms 111 to vibrate in the circumferential direction whose center is rotational axis 299. The type of driving members 211 is not particularly limited. A piezoelectric element, a magnetostrictor, or the like can exemplify the type of driving members 211. In this embodiment, driving members 211 each are a piezoelectric element, and include a material containing lead zirconate titanate (PZT). For each driving member 211, a thin-film stacking-type piezoelectric actuator having a stacked body structure in which an electrode and a piezoelectric body are stacked is used. With this, it is possible to make driving members 211 thinner.

Positions to which driving members 211 are attached are not particularly limited; however, driving members 211 may be suitably attached to positions at which tuning fork vibrators 110 are caused to effectively vibrate. In this embodiment, driving members 211 are provided on respective surfaces of arms 111 of tuning fork vibrators 110. With this, it is possible to (i) cause the pair of vibrator groups 101 to strongly, integrally vibrate, (ii) increase the oscillation angle of reflective body 120, and (ii) cause reflective body 120 to rotate at a high frequency. Driving members 211 are of a narrow, plate-like shape which are disposed on respective surfaces of arms 111 along rotational axis 299. Application of a voltage that periodically fluctuates causes driving members 211 to repeatedly expand and contract in the rotational axis 299 direction, thereby causing tuning fork vibrators 110 to vibrate.

Drive control devices 212 supply electric power (including magnetic force) that causes tuning fork vibrators 110 to vibrate by periodically deforming driving members 211. In this embodiment, drive control devices 212 are provided on base 140 and the surfaces of tuning fork vibrators 110 using the MEMS technique. Drive control devices 212 are connected to a line (not illustrated) electrically connected with each driving member 211, and supply a voltage that periodically fluctuates to driving members 211. Drive control devices 212 drive tuning fork vibrators 110 such that rotational vibrations produced by tuning fork vibrators 110 in each vibrator group 101 are in phase around rotational axis 299. Moreover, drive control devices 212 supply a periodic voltage to driving members 211 such that the pair of vibrator groups 101 are driven to cause the rotational vibrations produced by reflective body 120 and the rotational vibrations produced by the pair of vibrator groups 101 to be in opposite phase around rotational axis 299.

According to the above-described optical reflector element 100 and optical reflector system 200, a plurality of tuning fork vibrators 110 in each vibrator group 101 are cause to rotationally vibrate in phase for causing reflective body 120 to rotationally vibrate. For this reason, stress applied when optical reflector element 100 is driven is distributed, and an oscillation angle that leads to a mechanical fracture can be increased. Therefore, reflective body 120 can rotationally vibrate at a high frequency and with high amplitude using high torque, and long life can be ensured.

In addition, driving means 210 driving optical reflector element 100 such that rotational vibrations produced by the pair of vibrator groups 101 and rotational vibrations produced by reflective body 120 are in opposite phase enhances driving efficiency, or more specifically, increases an oscillation angle (oscillation angle characteristics) of reflective body 120 per unit power to be input to driving members 211, in addition to a stress distribution effect brought about by individual tuning fork vibrators 110 rotationally vibrating in phase.

Moreover, the use of a structure whose torsional rigidity decreases in the order from couplers 113 of tuning fork vibrators 110 farther away from reflective body 120 toward couplers 113 of tuning fork vibrators 110 closer to reflective body 120 allows torque produced by rotational vibrations produced by each tuning fork vibrator 110 to be effectively transmitted to reflective body 120, thereby enhancing driving efficiency of optical reflector element 100.

In addition, the use of a structure in which a resonance frequency of rotational vibrations produced by each individual tuning fork vibrator 110 is substantially the same reduces a difference in stress applied when optical reflector element 100 is driven, and increases an oscillation angle of reflective body 120 which leads to a mechanical fracture due to concentration of stress.

Note that the present disclosure is not limited to the above-described embodiment. For example, different embodiments realized by combining optional structural elements described in the present specification or by excluding some of the structural elements described in the present specification may be embodiments of the present disclosure. Moreover, the present disclosure also includes variations obtained by applying various modifications conceivable to those skilled in the art to each embodiment without departing from the essence of the present disclosure, or in other words, without departing from the meaning of wording recited in the claims.

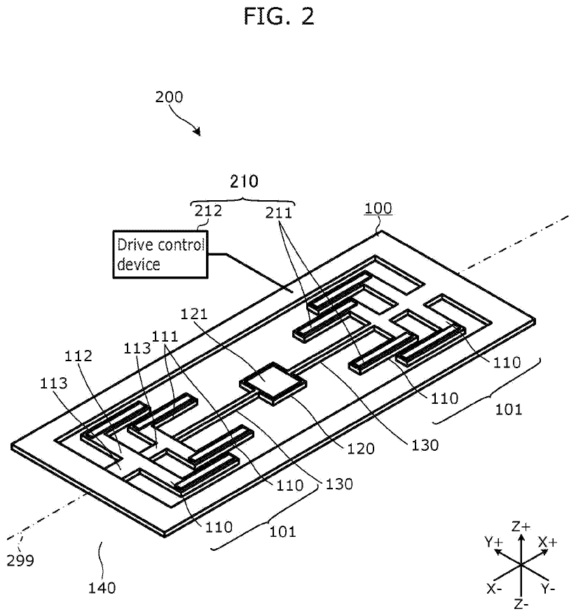

For example, as illustrated in FIG. 2, portions of arms 111 of one tuning fork vibrator 110 in vibrator group 101 may be disposed between arms 111 of the other tuning fork vibrator 110 such that tuning fork vibrators 110 overlap in the rotational axis 299 direction. Disposition of tuning fork vibrators 110 as described above can shorten the length in the rotational axis 299 direction of optical reflector element 100.

Moreover, as illustrated in FIG. 2, the length of couplers 113 of tuning fork vibrators 110 in the rotational axis 299 direction may be substantially the same. In this case, an area size of couplers 113 which is orthogonal to rotational axis 299 may be increased in the order from reflective body 120 toward the outside to increase torsional rigidity in the order from reflective body 120 toward the outside. In the case illustrated in FIG. 2, couplers 113 have the same length in the rotational axis 299 direction and the same thickness (Z axis direction as shown in the diagram). Accordingly, the width (a length in the Y axis direction as shown in the diagram) of couplers 113 may be increased in the order from reflective body 120 toward the outside.

In addition, arms 111, connectors 112, and couplers 113 need not be of a perfect linear shape. Arms 111, connectors 112, and couplers 113 may be flexed or curved.

The case where a single vibrator group 101 includes two tuning fork vibrators 110 has been hereinbefore described; however, a single vibrator group 101 may include three or more tuning fork vibrators 110. In this case, it is suitable to dispose the vibration centers of a plurality of tuning fork vibrators 110 on rotational axis 299.

The case where a pair of arms 111 is provided with two driving members 211 to cause tuning fork vibrator 110 to rotationally vibrate has been hereinbefore described; however, the formation of driving member 211 on at least one of the arms included in tuning fork vibrator 110 can realize operations same as the operations performed by optical reflector element 100 as described above. The foregoing uses vibration characteristics of a tuning fork. More specifically, the foregoing uses a characteristic that enables either one of the arms to vibrate by propagation of kinetic energy via connector 112 when the other arm is driven.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The optical reflector element and optical reflector system according to the present disclosure are useful for a small display device, a small projector, an in-vehicle head-up display device, an electrographic copying machine, a laser-beam printer, an optical scanner, an optical radar, etc.

1. An optical reflector element comprising:
vibrator groups each of which includes tuning fork vibrators that are coupled together such that vibration centers of the tuning fork vibrators align on an imaginary rotational axis;
a reflective body;
supports that couple the vibrator groups and the reflective body together; and
a base to which the vibrator groups are coupled in a manner that allows the vibrator groups to vibrate.

2. The optical reflector element according to claim 1, wherein
the vibrator groups are disposed with the reflective body interposed therebetween,
the supports couple a pair of the vibrator groups and the reflective body together, and
the base is a base to which the pair of the vibrator groups are coupled in a manner that allows the pair of the vibrator groups to vibrate.

3. The optical reflector element according to claim 1, wherein
around the rotational axis, a resonance frequency of rotational vibrations produced by each individual tuning fork vibrator included in the tuning fork vibrators is substantially same.

4. The optical reflector element according to claim 1, wherein
torsional rigidity of couplers between the base and the vibrator groups is greater than torsional rigidity of a coupler between tuning fork vibrators in each of the vibrator groups, and the torsional rigidity of the coupler between the tuning fork vibrators in the each of the vibrator groups is greater than torsional rigidity of the supports.

5. An optical reflector system comprising:
vibrator groups each of which includes tuning fork vibrators that are coupled together such that vibration centers of the tuning fork vibrators align on an imaginary rotational axis;
a reflective body interposed between the vibrator groups;
supports that couple the vibrator groups and the reflective body together;
a base to which the vibrator groups are coupled in a manner that allows the vibrator groups to vibrate; and
driving means that drive the tuning fork vibrators such that rotational vibrations produced by the tuning fork vibrators in the vibrator groups are in phase around the rotational axis.

6. The optical reflector system according to claim 5, wherein
the vibrator groups are disposed with the reflective body interposed therebetween,
the supports couple a pair of the vibrator groups and the reflective body together,
the base is a base to which the pair of the vibrator groups are coupled in a manner that allows the pair of the vibrator groups to vibrate, and
the optical reflector system comprises the driving means that drive the tuning fork vibrators such that rotational vibrations produced by the tuning fork vibrators the vibrator groups are in phase around the rotational axis.

7. The optical reflector system according to claim 5, wherein
the driving means drive a pair of the vibrator groups such that rotational vibrations produced by the reflective body and rotational vibrations produced by the pair of the vibrator groups are in opposite phase around the rotational axis.

8. The optical reflector system according to claim 6, wherein
the driving means drives the pair of the vibrator groups such that rotational vibrations produced by the reflective body and rotational vibrations produced by the pair of the vibrator groups are in opposite phase around the rotational axis.
